(19) United States
(12) Patent Application Publication
(10) Pub. No.: US 2022/0394854 A1
(43) Pub. Date: Dec. 8, 2022

(54) METHOD AND SYSTEM FOR MAKING COIL FOR WIRELESS CHARGING

(71) Applicant: ELECTRONICS AND TELECOMMUNICATIONS RESEARCH INSTITUTE, Daejeon (KR)

(72) Inventors: Jung Ick MOON, Daejeon (KR); Gwangzeen KO, Daejeon (KR); Sang-Won KIM, Daejeon (KR); Seong-Min KIM, Daejeon (KR); Woo Jin BYUN, Daejeon (KR); Je Hoon YUN, Daejeon (KR); In Kui CHO, Daejeon (KR)

(21) Appl. No.: 17/826,327

(22) Filed: May 27, 2022

(30) Foreign Application Priority Data
Jun. 4, 2021 (KR) 10-2021-0073035
Mar. 30, 2022 (KR) 10-2022-0039890

(51) Int. Cl. H05K 1/16; H05K 3/00; B29C 64/112; H05K 3/12; H02J 50/00; H02J 50/10

(52) U.S. Cl. CPC H05K 1/165; H05K 3/0005; B29C 64/112; H05K 3/125; H02J 50/005; H02J 50/10

(57) ABSTRACT

A method and system for manufacturing a coil for wireless charging are disclosed herein. The method may include manufacturing a printed circuit board, generating a coil-shaped metal pattern on the printed circuit board, and generating an additional metal pattern on the top of the metal pattern using a 3D metal printer.

### CROSS-REFERENCE TO RELATED APPLICATIONS

This application claims the benefit of Korean Patent Application No. 10-2021-0073035, filed on Jun. 4, 2021, and Korean Patent Application No. 10-2022-0039890, filed on Mar. 30, 2022, in the Korean Intellectual Property Office, the entire disclosure of which is incorporated herein by reference for all purposes.

### BACKGROUND

### 1. Field of the Invention

The present disclosure relates to a method and system for designing and manufacturing a low-loss three-dimensional coil on a printed circuit board.

### 2. Description of Related Art

In wireless charging technology using magnetic fields, a coil is an essential component of the system. Conventional coils are made of a Litz wire, which is a thick single conductor consisting of bundles of thin copper wires according to characteristics of high-frequency copper wires.

As the Litz wire is a bundle of many metal wires in a certain pattern, the Litz wire must go through a manufacturing process using a special machine, and the finished Litz wire is attached to a printed circuit board (PCB), a ferrite, or other accessories.

However, since an on-board charging method is used in a small wireless charging system, manufacturing a circuit and the coil in an all-in-one form is advantageous for commercialization of the technology.

Therefore, a method of manufacturing the coil directly on the printed circuit board without attaching the Litz wire is called for.

### SUMMARY

Example embodiments may provide a method and system for manufacturing a coil on a printed circuit board directly without using a Litz wire by generating an additional metal pattern on the metal pattern using a 3D metal printer.

A method of manufacturing a coil for wireless charging according to an embodiment of the present disclosure may include manufacturing a printed circuit board; generating a coil-shaped metal pattern on the printed circuit board; and generating an additional metal pattern on the top of the metal pattern using a 3D metal printer.

Generating the additional metal pattern of the method of manufacturing the coil for wireless charging according to an embodiment of the present disclosure may determine a reference point on the printed circuit board according to design requirements and generate an additional metal pattern on a position corresponding to the reference point in the metal pattern.

The method of manufacturing the coil for wireless charging according to an embodiment of the present disclosure may further include generating the coil-shaped metal pattern on the bottom of the printed circuit board. The generation of the additional metal pattern may generate an additional metal pattern on the bottom of the metal pattern generated on the bottom of the printed circuit board.

The method of manufacturing the coil for wireless charging according to an embodiment of the present disclosure may include manufacturing a printed circuit board; generating the coil-shaped metal pattern on the printed circuit board; generating an additional metal pattern on the top of the metal pattern with a 3D metal printer; generating a metal body using the 3D metal printer; and bonding the metal body to the additional metal pattern.

In the bonding stage of the method for manufacturing the coil for wireless charging according to an embodiment herein, the metal body may be bonded to the additional metal pattern by bending the additional metal pattern according to the position of the metal body.

In the bonding stage of the method for manufacturing the coil for wireless charging according to an embodiment herein, the metal body may be inserted into a groove formed on the additional metal pattern to be bonded to the additional metal pattern.

A system for manufacturing the coil for wireless charging according to an embodiment herein may include: a substrate manufacturing device for manufacturing a printed circuit board; a metal-pattern manufacturing device for generating a coil-shaped metal pattern on the top of the printed circuit board; and a 3D metal printer that generates an additional metal pattern on the top of the metal pattern.

The 3D metal printer of the coil manufacturing system for coil for wireless charging according to an embodiment herein may determine the reference point on the printed circuit board according to design requirements and generate the additional metal pattern on the position corresponding to the reference point in the metal pattern.

The metal-pattern manufacturing device of the coil for wireless-charging manufacturing system according to an embodiment herein may generate the coil-shaped metal pattern on the bottom of the printed circuit board, and the 3D metal printer may generate the additional metal pattern on the bottom of the metal pattern generated on the bottom of the printed circuit board.

The system for manufacturing the coil for wireless charging according to an embodiment herein may further include a bonding device that bonds an inner body to the additional metal pattern, and the 3D metal printer may generate the metal body when the printed circuit board does not include a via hole.

The bonding device of the coil of the wireless-charging manufacturing system according to an embodiment herein may bond the metal body to the additional metal pattern by bending the additional metal pattern according to the position of the metal body.

The bonding device of the coil of the wireless-charging manufacturing system according to an embodiment herein may insert the metal body into the groove formed on the additional metal pattern to bond the metal body to the additional metal pattern.

According to an embodiment of the present disclosure, a coil may be manufactured directly on a printed circuit board without using a Litz wire by generating an additional metal pattern on a metal pattern using a 3D metal printer.

In addition, according to an embodiment herein, generating an additional metal pattern on a metal pattern using a 3D metal printer may be advantageous for the mass production of an on-board wireless charging system.

Also, according to an embodiment herein, the resistance of an antenna or a transmission line using the printed circuit board may be reduced.

### BRIEF DESCRIPTION OF THE DRAWINGS

FIG. 1 is a diagram illustrating a coil of a wireless-charging manufacturing system according to an embodiment of the present disclosure.

FIG. 2 is an example of a coil for wireless charging manufactured according to the first embodiment herein.

FIG. 3 is another example of the coil for wireless charging manufactured according to the second embodiment herein.

FIG. 4 is an example of bonding between an additional metal pattern and a metal body of the coil for wireless charging manufactured according to the second embodiment herein.

FIG. 5 is a flowchart illustrating a method of manufacturing the coil for wireless charging according to the first embodiment herein.

FIG. 6 is a flowchart illustrating the method of manufacturing the coil for wireless charging according to the second embodiment herein.

### DETAILED DESCRIPTION OF THE INVENTION

Hereinafter, embodiments will be described in detail with reference to the accompanying drawings. A method of manufacturing a coil for wireless charging according to an embodiment of the present disclosure may be performed by a coil of a wireless-charging manufacturing system.

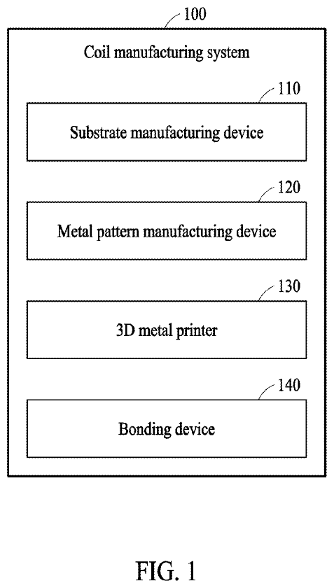

FIG. 1 is a diagram illustrating a coil of a wireless-charging manufacturing system according to an embodiment of the present disclosure.

A coil of a wireless-charging manufacturing-control device 100 may include a substrate manufacturing device 110, a metal-pattern manufacturing device 120, a 3D metal printer 130, and a bonding device 140 as illustrated in FIG. 1.

The substrate manufacturing device 110 may manufacture a printed circuit board. In this case, the printed circuit board manufactured by the substrate manufacturing device 110 may include a via hole for electrically connecting the upper surface and the lower surface.

Also, when the printed circuit board manufactured by the substrate manufacturing device 110 includes the via hole, the coil of the wireless-charging manufacturing-control device 100 may manufacture the coil for wireless charging according to the first embodiment. In addition, when the printed circuit board manufactured by the substrate manufacturing device 110 does not include the via hole, the coil of the wireless-charging manufacturing-control device 100 may manufacture the coil for wireless charging according to the second embodiment.

The metal-pattern manufacturing device 120 may generate a coil-shaped metal pattern on the top of the printed circuit board. Also, the metal-pattern manufacturing device 120 may generate the coil-shaped metal pattern on the bottom of the printed circuit board.

The 3D metal printer 130 may generate an additional metal pattern on the top of the metal pattern. In this case, the 3D metal printer 130 may determine a reference point on the printed circuit board according to design requirements and generate the additional metal pattern at a position corresponding to the reference point in the metal pattern. Also, the 3D metal printer 130 may generate the additional metal pattern on the bottom of the metal pattern generated on the bottom of the printed circuit board.

When the printed circuit board does not include the via hole, the 3D metal printer 130 may generate a metal body. In addition, the bonding device 140 may manufacture the coil for wireless charging by bonding the metal body to the additional metal pattern. In this case, the bonding device 140 may bond the metal body to the additional metal pattern by bending the additional metal pattern according to the position of the metal body. Also, the bonding device 140 may insert the metal body into a groove formed in the additional metal pattern to bond the metal body to the additional metal pattern.

Also, in some embodiments, the metal pattern may not be manufactured on the printed circuit board. In this case, the 3D metal printer 130 may set a reference point on the printed circuit board and generate the metal pattern of the coil on a dielectric material of the printed circuit board.

The wireless-charging-coil manufacturing-control device 100 may manufacture a coil directly on the printed circuit board without using a Litz wire in the wireless charging system.

Thus, the wireless-charging-coil manufacturing-control device 100 may be advantageous for the mass production of an on-board wireless charging system. In addition, the wireless-charging-coil manufacturing-control device 100 may reduce the resistance of an antenna or a transmission line using the printed circuit board.

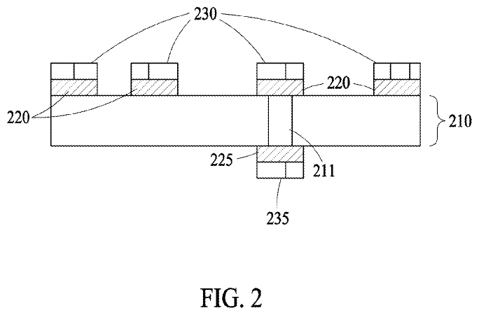

FIG. 2 is an example of a coil for wireless charging manufactured according to the first embodiment herein.

As illustrated in FIG. 2, for the coil for wireless charging manufactured according to the first embodiment, metal patterns 220 and 225 may be manufactured on the top and the bottom of the printed circuit board 210 respectively on which a via hole 211 is formed. In addition, the 3D metal printer 130 may increase the height of a metal conductor included in the coil for wireless charging by generating an additional metal pattern 230 on the top of the metal pattern 220. In addition, the 3D metal printer 130 may increase the height of the metal pattern on the bottom of the coil for wireless charging by generating an additional metal pattern 235 on a lower part of a metal pattern 225.

Also, the 3D metal printer 130 may adjust the height of the metal conductor included in the coil for wireless charging to be different by section by generating the additional metal pattern 230 only in a part of the metal pattern 220.

The operation of adjusting the height of the metal conductor included in the coil for wireless charging to be different by section may be performed when the area of a coil needs to be reduced on the printed circuit board or when the width of a wire needs to be narrowed due to various design requirements. Even though the resistance of the metal conductor included in the coil for wireless charging may increase, the increase in height may decrease the resistance.

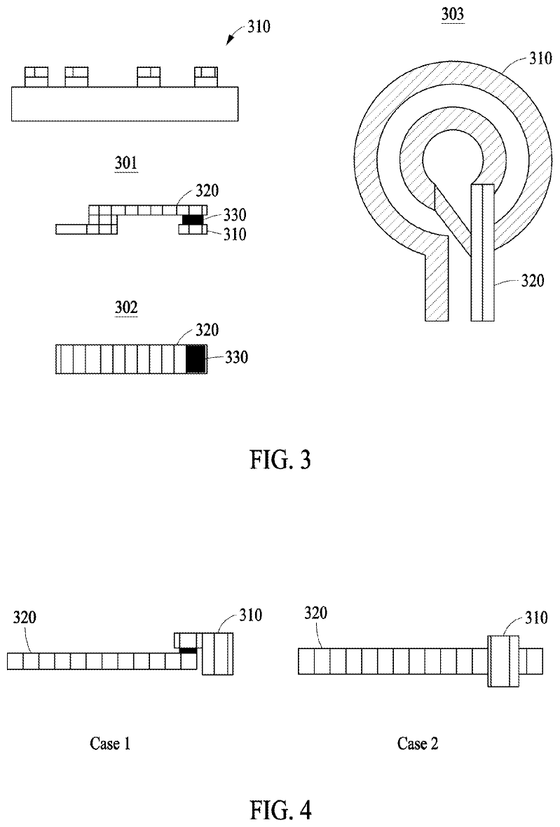

FIG. 3 is another example of the coil for wireless charging manufactured according to the second embodiment herein.

The second embodiment herein may be used when it is difficult to manufacture an inductor using a via hole. First, the 3D metal printer 130 may generate an additional metal pattern on the top of a metal pattern. For example, the 3D metal printer 130 may generate the additional metal pattern using copper or a mixture of copper and synthetic resin.

Then, the 3D metal printer 130 may generate a metal body 320. In this case, the 3D metal printer 130 may generate the metal body 320 at a location other than the top of a printed circuit board 310.

Then, the bonding device 140 may move the metal body 320 from the position where the metal body 320 was generated to the top of the printed circuit board 310. In addition, the bonding device 140 may manufacture the coil for wireless charging by bonding 330 the substrate 310 on which the additional metal pattern is generated and the metal body 320.

In this case, the printed circuit board 310 and the metal body 320 on which the additional metal pattern is generated may be bonded surface-to-surface by welding or soldering as illustrated in FIG. 3.

Also, the bonding device 140 may be a device that supports the position where the metal body 320 is to be formed using a non-metallic body. At this point, the 3D metal printer 130 may generate the metal body 320 on the additional metal pattern. After the metal body 320 generated by the 3D metal printer 130 is hardened, the bonding device 140 removes the support, and the additional metal pattern and the metal body 320 may be bonded.

FIG. 4 is an example of bonding between an additional metal pattern and a metal body of the coil for wireless charging manufactured according to the second embodiment herein.

The bonded area 330 between the printed circuit board 310 on which the additional metal pattern is generated and the metal body 320, as illustrated in case 1 of FIG. 4, may be a structure where the printed circuit board 310 on which the additional metal pattern is generated is bent toward the metal body to bond the metal body 320 to the additional metal pattern 310.

In addition, the bonded area 330 between the substrate 310 on which the additional metal pattern is generated and the metal body 320, as illustrated in case 2 of FIG. 4, may be a structure where a groove is formed on the substrate 310 on which the additional metal pattern is generated, and the metal body 320 is inserted into the groove to bond the metal body 320 to the additional metal pattern 310.

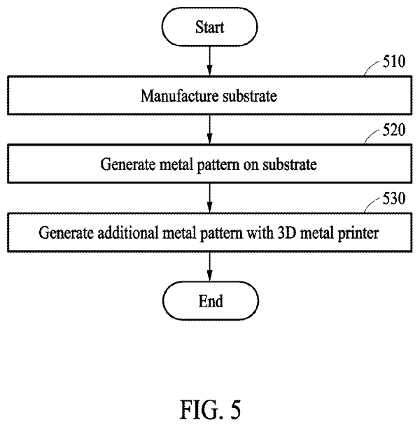

FIG. 5 is a flowchart illustrating a method of manufacturing the coil for wireless charging according to the first embodiment herein.

In operation 510, the substrate manufacturing device 110 may manufacture a printed circuit board.

In operation 520, the metal-pattern manufacturing device 120 may generate the coil-shaped metal pattern on the printed circuit board manufactured in operation 510. In this case, the metal-pattern manufacturing device 120 may generate the coil-shaped metal pattern on the bottom of the printed circuit board.

In operation 530, the 3D metal printer 130 may generate an additional metal pattern on the top of the metal pattern generated in operation 520. In this case, the 3D metal printer 130 may determine a reference point on the printed circuit board according to design requirements and generate the additional metal pattern at a position corresponding to the reference point in the metal pattern.

Also, the 3D metal printer 130 may generate the additional metal pattern on the bottom of the metal pattern generated on the bottom of the printed circuit board.

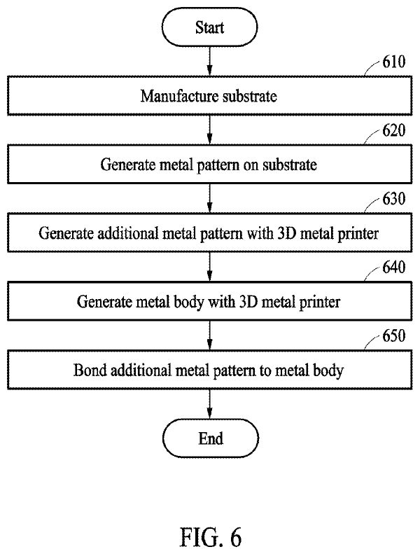

FIG. 6 is a flowchart illustrating the method of manufacturing the coil for wireless charging according to the second embodiment herein.

In operation 610, the substrate manufacturing device 110 may manufacture the printed circuit board.

In operation 620, the metal-pattern manufacturing device 120 may generate a coil-shaped metal pattern on the top of the printed circuit board manufactured in operation 610.

In operation 630, the 3D metal printer 130 may generate an additional metal pattern on the top of the metal pattern generated in operation 620.

In operation 640, the 3D metal printer 130 may generate a metal body.

In operation 650, the bonding device 140 may bond the metal body generated in operation 640 to the additional metal pattern generated in operation 630. In this case, the bonding device 140 may bond the metal body to the additional metal pattern by bending the additional metal pattern according to the position of the metal body. Also, the bonding device 140 may insert the metal body into a groove formed in the additional metal pattern to bond the metal body to the additional metal pattern.

According to the present disclosure, a coil may be directly manufactured on a printed circuit board without using a Litz wire by generating an additional metal pattern on the metal pattern using a 3D metal printer.

Therefore, the present disclosure may be advantageous for mass production of an on-board wireless charging system. In addition, the present disclosure may reduce the resistance of an antenna or a transmission line using a printed circuit board.

The method according to example embodiments may be written in a computer-executable program and may be implemented as various recording media such as magnetic storage media, optical reading media, or digital storage media.

Various techniques described herein may be implemented in digital electronic circuitry, computer hardware, firmware, software, or combinations thereof. The implementations may be achieved as a computer program product, i.e., a computer program tangibly embodied in an information carrier, e.g., in a machine-readable storage device (for example, a computer-readable medium) or in a propagated signal, for processing by, or to control an operation of, a data processing device, e.g., a programmable processor, a computer, or multiple computers. computer program, such as the computer program(s) described above, may be written in any form of a programming language, including compiled or interpreted languages, and may be deployed in any form, including as a stand-alone program or as a module, a component, a subroutine, or other units suitable for use in a computing environment. A computer program may be deployed to be processed on one computer or multiple computers at one site or distributed across multiple sites and interconnected by a communication network.

Processors suitable for processing of a computer program include, by way of example, both general and special purpose microprocessors, and any one or more processors of any kind of digital computer. Generally, a processor will receive instructions and data from a read-only memory or a random-access memory, or both. Elements of a computer may include at least one processor for executing instructions and one or more memory devices for storing instructions and data. Generally, a computer also may include, or be operatively coupled to receive data from or transfer data to, or both, one or more mass storage devices for storing data, e.g., magnetic, magneto-optical disks, or optical disks. Examples of information carriers suitable for embodying computer program instructions and data include semiconductor memory devices, e.g., magnetic media such as hard disks, floppy disks, and magnetic tape, optical media such as compact disk read only memory (CD-ROM) or digital video disks (DVDs), magneto-optical media such as floptical disks, read-only memory (ROM), random-access memory (RAM), flash memory, erasable programmable ROM (EPROM), or electrically erasable programmable ROM (EEPROM). The processor and the memory may be supplemented by, or incorporated in special purpose logic circuitry.

In addition, non-transitory computer-readable media may be any available media that may be accessed by a computer and may include both computer storage media and transmission media.

Although the present specification includes details of a plurality of specific example embodiments, the details should not be construed as limiting any disclosure or a scope that can be claimed, but rather should be construed as being descriptions of features that may be peculiar to specific example embodiments of specific disclosures. Specific features described in the present specification in the context of individual example embodiments may be combined and implemented in a single example embodiment. On the contrary, various features described in the context of a single example embodiment may be implemented in a plurality of example embodiments individually or in any appropriate sub-combination. Furthermore, although features may operate in a specific combination and may be initially depicted as being claimed, one or more features of a claimed combination may be excluded from the combination in some cases, and the claimed combination may be changed into a sub-combination or a modification of the sub-combination.

Likewise, although operations are depicted in a specific order in the drawings, it should not be understood that the operations must be performed in the depicted specific order or sequential order or all the shown operations must be performed in order to obtain a preferred result. In specific cases, multitasking and parallel processing may be advantageous. In addition, it should not be understood that the separation of various device components of the aforementioned example embodiments to is required for all the example embodiments, and it should be understood that the aforementioned program components and devices may be integrated into a single software product or packaged into multiple software products.

The example embodiments disclosed in the present specification and the drawings are intended merely to present specific examples in order to aid in understanding of the present disclosure, but are not intended to limit the scope of the present disclosure. It will be apparent to those skilled in the art that various modifications based on the technical spirit of the present disclosure, as well as the disclosed example embodiments, may be made.

What is claimed is:

1. A method of manufacturing a coil for wireless charging, comprising:
manufacturing a printed circuit board;
generating a coil-shaped metal pattern on the printed circuit board; and
generating an additional metal pattern on a top of the metal pattern using a 3D metal printer.

2. The method of claim 1, wherein:
generating the additional metal pattern determines a reference point on the printed circuit board according to design requirements; and
generates the additional metal pattern at a position corresponding to the reference point on the metal pattern.

3. The method of claim 1, further comprising generating the coil-shaped metal pattern on the bottom of the printed circuit board,
wherein the generating of the additional metal pattern is the method of manufacturing the coil for wireless charging to generate the additional metal pattern on the bottom of the metal pattern generated on the bottom of the printed circuit board.

4. A method of manufacturing the coil for wireless charging, comprising:
manufacturing a printed circuit board;
generating a coil-shaped metal pattern on a top of the printed circuit board;
generating an additional metal pattern on a top of the metal pattern using a 3D metal printer;
generating a metal body using the 3D metal printer; and
bonding the metal body to the additional metal pattern.

5. The method of claim 4, wherein the bonding stage bonds the metal body to the additional metal pattern by bending the additional metal pattern according to the position of the metal body.

6. The method of claim 4, wherein the bonding stage bonds the metal body to the additional metal pattern by inserting the metal body into a groove formed on the additional metal pattern.

7. A system for manufacturing a coil for wireless charging, comprising:
a substrate manufacturing device for manufacturing a printed circuit board;
a metal-pattern manufacturing device for generating a coil-shaped metal pattern on a top of the printed circuit board; and
a 3D metal printer for generating an additional metal pattern on a top of the metal pattern.

8. The system of claim 7, wherein:
the 3D metal printer is the system for manufacturing the coil for wireless charging that determines the reference point on the printed circuit board according to design requirements; and
generates the additional metal pattern at the position corresponding to the reference point in the metal pattern.

9. The system of claim 7, wherein:
the metal-pattern manufacturing device generates the coil-shaped metal pattern on the bottom of the printed circuit board; and
the 3D metal printer is the system for manufacturing the coil for wireless charging that generates the additional metal pattern on the bottom of the metal pattern generated on the bottom of the printed circuit board.

10. The system of claim 7, further comprising the bonding device that bonds the metal body to the additional metal pattern,
wherein the 3D metal printer is the system for manufacturing the coil for wireless charging that generates the metal body when the printed circuit board does not include a via hole.

11. The system of claim 10, wherein the bonding device bonds the metal body to the additional metal pattern by bending the additional metal pattern according to the position of the metal body.

12. The system of claim 10, wherein the bonding device is the system for manufacturing the coil for wireless charging that bonds the metal body to the additional metal pattern by inserting the metal body into the groove formed on the additional metal pattern.
